(19) United States
(12) Patent Application Publication
(10) Pub. No.: US 2021/0267078 A1
(43) Pub. Date: Aug. 26, 2021

(54) ELECTRONIC DEVICE AND STAND THEREOF

(71) Applicants: ShenZhen Hongfei Precision Technology Co.,Ltd., Shenzhen (CN); HON HAI PRECISION INDUSTRY CO., LTD., New Taipei (TW)

(72) Inventors: WEN-PIN WANG, New Taipei (TW); LI-WEI CHEN, New Taipei (TW); HSUEH-HO HAN, New Taipei (TW)

(21) Appl. No.: 16/802,271

(22) Filed: Feb. 26, 2020

(51) Int. Cl. H05K 5/02; F16M 11/04; F16M 11/22; F16M 13/02

(52) U.S. Cl. CPC H05K 5/0234; H05K 5/0204; F16M 13/02; F16M 11/22; F16M 11/04

(57) ABSTRACT

A device stand for supporting an electronic panel that is covered by a rear panel includes a first stand surface and a second stand surface that intersects the first stand surface. A plurality of first stand holes in a first hole group is located on the first stand surface and a plurality of second stand holes in a second hole group is located on the second stand surface. The device stand is removably coupled to the rear panel through the plurality of first stand holes when the electronic panel is disposed on a first plane and is removably coupled to the rear panel through the plurality of second stand holes when the electronic panel is mounted on a second plane different from the first plane.

### FIELD

The present disclosure generally relates to an electronic device including a stand for supporting an electronic panel on a first plane or mounting the electronic panel on a second plane.

### BACKGROUND

Display panels have been widely used in televisions, laptops, tablets, or other electronics for conveying information or displaying graphics, video, or text. A display panel may be coupled to a rear cover to form a display device. For the convenience of the viewer, the display device may be coupled to a rack or a mount and then installed onto a corner, or onto a wall. In addition, the display device may be coupled to a stand and then mounted on a desk, or on a flat surface.

A user cannot put the display device on the flat surface when the user only has the rack or the mount. The user cannot mount the display device on the wall when the user only has the stand. In addition, the user can select one of the mount and the stand for supporting the display device when the user has both the mount and the stand. However, the unused one of the mount and the stand may be a redundant element for the user.

### SUMMARY

The present disclosure provides a device stand. The device stand for supporting an electronic panel covered by a rear panel has a first stand surface and a second stand surface intersected with the first stand surface. A plurality of first stand holes in a first hole group is located at the first stand surface, and a plurality of second stand holes in a second hole group is located at the second stand surface. The device stand is removably coupled to the rear panel through one of the first hole group and the second hole group. The device stand is coupled to the rear panel through the plurality of first stand holes when the electronic panel is disposed on a first plane. The device stand is coupled to the rear panel through the plurality of second stand holes when the electronic panel is mounted on a second plane different from the first plane.

### BRIEF DESCRIPTION OF THE DRAWINGS

Aspects of the exemplary disclosure are best understood from the following detailed description when read with the accompanying figures. Various features are not drawn to such that dimensions of various features may be arbitrarily increased or reduced for clarity of discussion.

FIG. 1A and FIG. 1B illustrate two perspective views of an electronic device in accordance with an embodiment of the present disclosure.

FIG. 2A and FIG. 2B illustrate two perspective views of a device stand of the electronic device of FIG. 1 in accordance with an embodiment of the present disclosure.

FIG. 3 illustrates an exploded view of an electronic device of FIG. 1A in accordance with an embodiment of the present disclosure.

FIG. 4A and FIG. 4B illustrate two perspective views of an electronic device in accordance with an embodiment of the present disclosure.

FIG. 5A and FIG. 5B illustrates two exploded views of an electronic device of FIG. 4A in accordance with an embodiment of the present disclosure.

### DETAILED DESCRIPTION

The following disclosure contains specific information pertaining to exemplary implementations in the present disclosure. The drawings in the present disclosure and their accompanying detailed disclosure are directed to merely exemplary implementations. However, the present disclosure is not limited to merely these exemplary implementations. Other variations and implementations of the present disclosure will occur to those skilled in the art. Unless noted otherwise, like or corresponding elements among the figures may be indicated by like or corresponding reference numerals. Moreover, the drawings and illustrations in the present disclosure are generally not to scale and are not intended to correspond to actual relative dimensions.

For the purpose of consistency and ease of understanding, like features are identified (although, in some examples, not shown) by numerals in the exemplary figures. However, the features in different implementations may be differed in other respects, and thus shall not be narrowly confined to what is shown in the figures.

The disclosure uses the phrases “in one implementation,” or “in some implementations,” which may each refer to one or more of the same or different implementations. The term “coupled” is defined as connected, directly or indirectly through intervening components and is not necessarily limited to physical connections. The term “comprising” means “including, but not necessarily limited to”; it specifically indicates open-ended inclusion or membership in the so-described combination, group, series and the equivalent.

Additionally, for the purposes of explanation and non-limitation, specific details such as functional entities, techniques, protocols, standard, and the like are set forth for providing an understanding of the described technology. In other examples, detailed disclosure of well-known methods, technologies, system, architectures, and the like are omitted so as not to obscure the disclosure with unnecessary details.

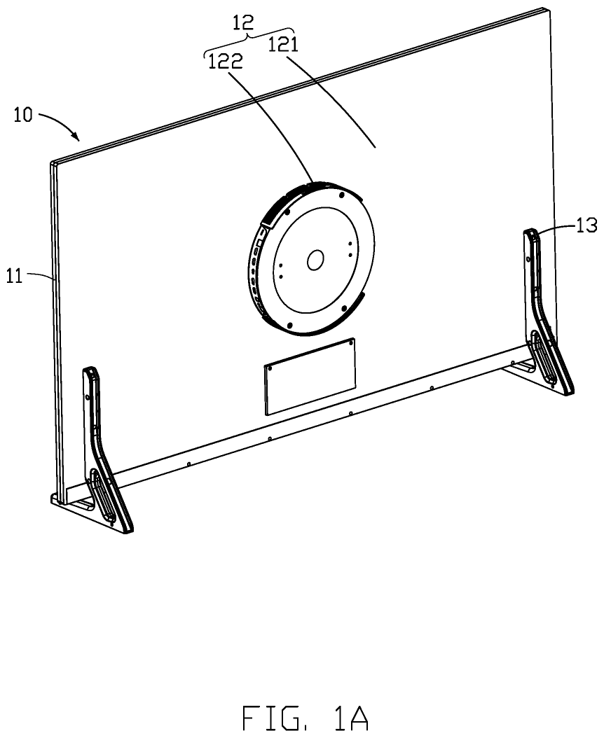

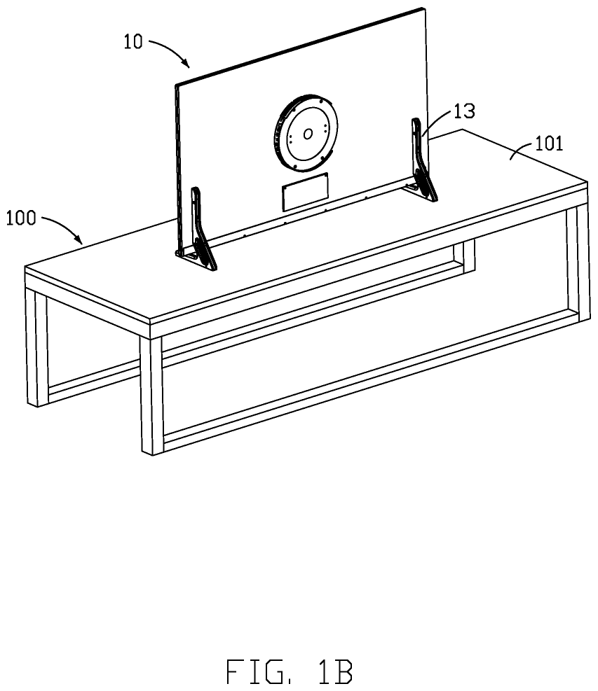

FIG. 1A and FIG. 1B illustrate two perspective views of an electronic device 10 in accordance with an embodiment of the present disclosure. In at least one implementation, an electronic device 10 may include an electronic panel 11, a rear panel 12 and a device stand 13. In at least one implementation, the rear panel 12 may further include a rear cover 121 covering the electronic panel 11 and a device bracket 122 coupled to the rear cover 121. In at least one implementation, the device stand 13 may be removably coupled to the rear cover 121. In at least one implementation, a user may directly put the electronic device 10 on a first plane 101 of a supporting device 100 when the device stand 13 is coupled to the rear cover 121. Thus, the electronic device 10 may be disposed on the first plane 101 of the supporting device 100. In the implementation, the supporting device 100 may be a shelf, a cabinet, a desk, or a table. In at least one implementation, the electronic device 10 may be a display device, and the electronic panel 11 may be a display panel.

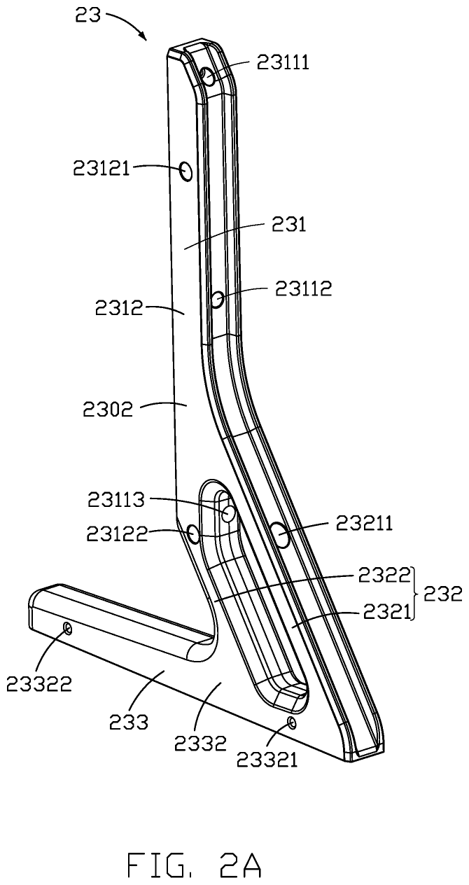

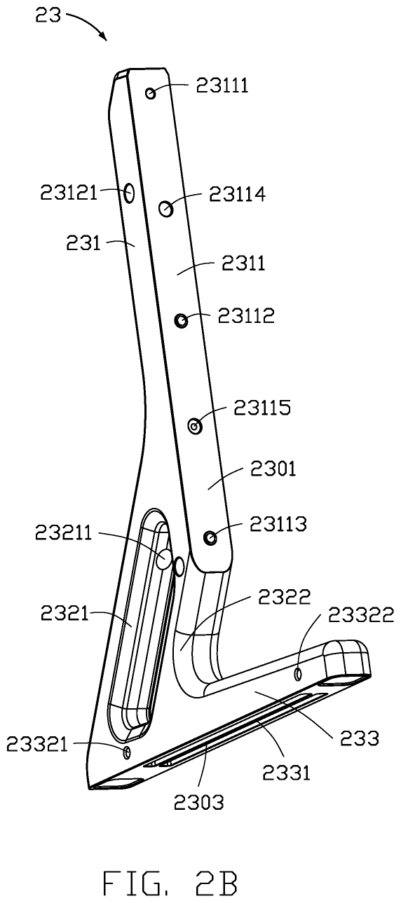

FIG. 2A and FIG. 2B illustrate two perspective views of a device stand 23 of the electronic device 10 of FIG. 1 in accordance with an embodiment of the present disclosure. In at least one implementation, the device stand 23 may include a stand connection 231, a stand arm 232, and a stand base 233. In at least one implementation, the device stand 23 may include a first stand surface 2301, a second stand surface 2302, and a third stand surface 2303. In the implementation, the second stand surface 2302 intersects the first stand surface 2301 and the third stand surface 2303. In at least one implementation, the third stand surface 2303 may be a first base surface 2331 of the stand base 233. In at least one implementation, the first stand surface 2301 may be a first connection surface 2311 of the stand connection 231. In at least one implementation, the second stand surface 2302 may include a second connection surface 2312 of the stand connection 231, an arm surface (not shown) of the stand arm 232, and a second base surface 2332 of the stand base 233.

In at least one implementation, the first connection surface 2311 may be perpendicular to the second connection surface 2312. In at least one implementation, a plurality of first stand holes 23111-23113 of a first hole group and a plurality of cover location pins 23114 and 23115 may be formed on the first connection surface 2311 that is identical to the first stand surface 2301. Referring to FIG. 1A, each of the plurality of first stand holes 23111-23113 may be a through hole for insertion of one of a plurality of cover connection pins into the stand connection 231 and the rear cover 121 in order to mount the device stand 23 on the rear cover 121. In at least one implementation, the rear cover 121 may include a plurality of cover location holes (not shown) corresponding to the cover location pins 23114 and 23115 for precisely and correctly mounting the device stand 23 on the rear cover 121. In the implementation, the rear cover 121 is coupled to the first connection surface 2311 when the stand connection 231 is coupled to the rear cover 121. In at least one implementation, the second connection surface 2312 of the second stand surface 2302 may include a second hole group having a plurality of second stand holes 23121-23122 In at least one implementation, each of the second stand holes 23121-23122 may be a through hole for insertion of one of a plurality of bracket connection pins (not shown) into the stand connection 231 and the device bracket 122 in order to mount the device stand 23 on the device bracket 122. In at least one implementation, the stand connection 23 may be removably coupled to one of the rear cover 121 of the device bracket 122 of the rear panel 12 through a corresponding one of the first hole group and the second hole group.

In at least one implementation, the stand connection 231 may be coupled to the stand base 233 by the stand arm 232. In at least one implementation, the stand connection 231 may be perpendicular to the stand base 233 and the stand arm 232 may be a tilted arm for connecting the stand connection 231 with the stand base 233. In at least one implementation, the stand arm 232 may include two connection arms 2321 and 2322. In at least one implementation, each of the two connection arms 2321 and 2322 has an arm intersection with the stand connection 231. In the implementation, the first stand hole 23113 may be located between the two arm intersections of the two connection arms 2321 and 232. In at least one implementation, the first connection arm 2321 may include a lock hole 23211 aligned with the first stand hole 23113. In at least one implementation, the lock hole 23211 may be a through hole. In addition, the lock hole 23211 may have a first hole size, and the first stand hole 23113 may have a second hole size smaller than the first hole size. In at least one implementation, the first hole size may also be greater than a pin size of the cover connection pins, and the pin size may be greater than the second hole size. Thus, referring to FIG. 1A, a specific one of the cover connection pins may penetrate through the lock hole 23211 and insert into the first stand hole 23113 to mount the device stand 23 on the rear cover 121 when the stand connection 231 is coupled to the rear cover 12 by the cover connection pins. In at least one implementation, a distance between the lock hole 23221 and the first stand hole 23113 may be shorter than a pin length of the cover connection pins. Thus, it may be necessary for the cover connection pin to be removed through the lock hole 23211, when the cover connection pin is removed from the first stand hole 23113. In at least one implementation, referring to FIG. 1A, a lock device (not shown) may penetrate through the lock pin 23221 to lock the electronic device 10 on the supporting device 100. In at least implementation, the distance between the lock hole 23211 and the first stand hole 23113 may be shorter than a sum of the length of the cover connection pins and a thickness of the lock device. Thus, the cover connection pin may not be removed from the first stand hole 23113 when the lock device penetrates through the lock pin 23211 to lock the electronic device 10. In at least one implementation, the lock device may be a wire rope locked to the supporting device 100.

In at least one implementation, the stand base 233 may include the first base surface 2331 and the second base surface 2332. In at least one implementation, the first base surface 2331 may be different from the second base surface 2332. In the implementation, the first base surface 2331 may be the third stand surface 2303 of the device stand 23. In at least one implementation, the first base surface 2331 may be perpendicular to the second base surface 2332. In at least one implementation, the second base surface 2332 may be on the same plane with the second connection surface 2312. Thus, the second base surface 2332 and the second connection surface 2312 may be included in the second stand surface 2302 of the device stand 23 In at least one implementation, referring to FIG. 1B, the device stand 23 may be coupled to the rear panel 121 through the plurality of first stand holes 23111-23113 when the electronic device 10 is disposed on the first plane 101. In addition, the first base surface 2331 of the stand base 233 may be in contact with the first plane 101 when the stand connection 231 is coupled to the rear cover 121 for placing the electronic device 10 on the first plane 101. In at least one implementation, a plurality of base pads (not shown) may be attached on the first base surface 2331 of the stand base 23. Thus, the base pads may be in contact with the first plane 101 and the first base surface 2331 of the stand base 233 may be in parallel with and separated from the first plane 101 when the electronic device 10 is disposed on the first plane 101. In at least one implementation, the second base surface 2332 may include a plurality of third stand holes 23321-23322. In at least one implementation, a plurality of mount connection pins (not shown) may be inserted into a mounting interface and the plurality of third stand holes 23321-23322 on the second base surface 2332 for mounting the mounting interface on the stand base 23 when the stand connection 231 is coupled to the device bracket 122.

In at least one implementation, the stand connection 231, the stand arm 232, and the stand base 233 may be three separate elements for assembly to form the device stand 23. In at least one implementation, the device stand 23 may be integrally formed as a one-piece stand without assembling the separate elements.

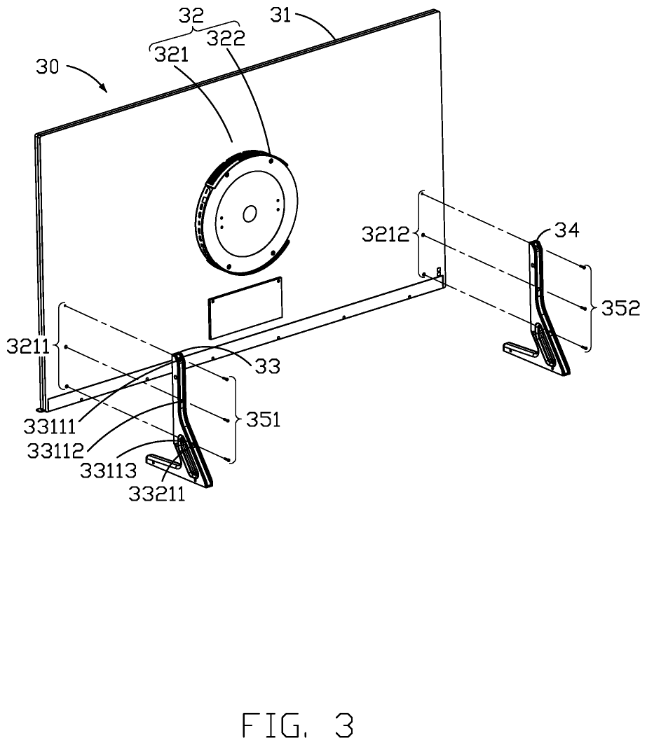

FIG. 3 illustrates an exploded view of an electronic device of FIG. 1A in accordance with an embodiment of the present disclosure. In at least one implementation, the electronic device 30 may include an electronic panel 31, a rear cover 321 and a device bracket 322 of a rear panel 32, a first device stand 33, a second device stand 34, a plurality of first cover connection pins 351, and a plurality of second cover connection pins 352. In at least one implementation, the rear cover 321 of the rear panel 32 may include a plurality of first stand connection holes 3211 and a plurality of second stand connection holes 3212. In at least one implementation, the first device stand 33 and second device stand 34 may include a plurality of first stand holes 33111-33113, and a lock hole 33211. In at least one implementation, the electronic device 30 may substantially correspond to the electronic device 10 in FIG. 1A.

In at least one implementation, each of the first cover connection pins 351 may insert into one of the first stand holes 33111-33113 of the first device stand 33 and a corresponding one of the first stand connection holes 3211 for mounting the first device stand 33 on the rear cover 321 of the rear panel 32. In at least one implementation, each of the second cover connection pins 352 may insert into one of the first stand holes of the second device stand 34 and a corresponding one of the second stand connection holes 3212 for mounting the second device stand 34 on the rear cover 321 of the rear panel 32. In at least one implementation, a specific one of the first cover connection pins 351 may penetrate through the lock hole 33211 before the specific first cover connection pin is inserted into the first stand hole 33113 for mounting the first device stand 33 on the rear cover 321. Thus, referring to FIG. 1A, the lock hole 33211 may be obstructed by a lock device (not shown) for preventing the specific first cover connection pin from being removed from the first device stand 33 and the rear cover 321, when the lock device penetrates through the lock hole 33211 for locking the electronic device 30 on a supporting device (e.g., supporting device 100 in FIG. 1B).

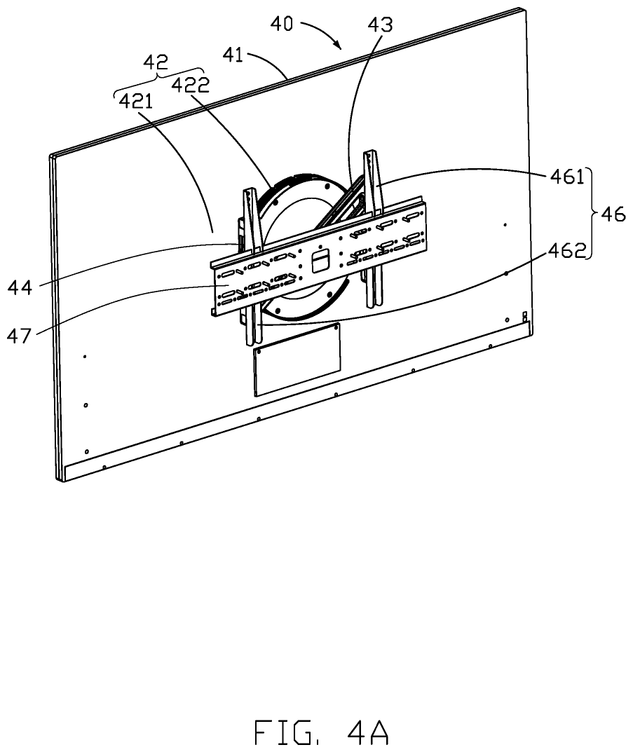

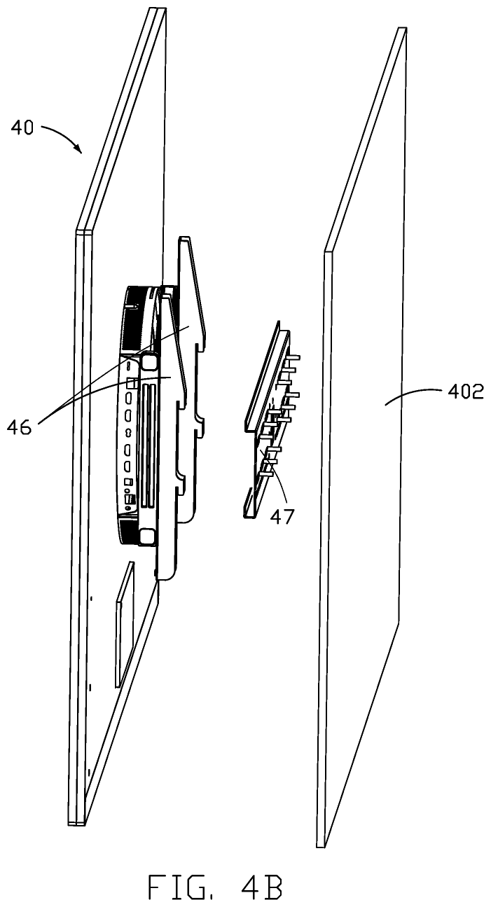

FIG. 4A and FIG. 4B illustrate two perspective views of an electronic device in accordance with an embodiment of the present disclosure. In at least one implementation, the electronic device 40 may include an electronic panel 41, a rear cover 421 and a device bracket 422 of the rear panel 42, a first device stand 43 and a second device stand 44. In at least one implementation, the first device stand 43 may be removably coupled to the device bracket 422, and the second device stand 44 may be removably coupled to the device bracket 422. In at least one implementation, a mounting interface 46 may be mounted on the first device stand 43 and the second device stand 44. In at least one implementation, the mounting interface 46 may include a first mounting rail 461 and a second mounting rail 462. In at least one implementation, the first mounting rail 461 may be mounted on the first device stand 43 and the second mounting rail 462 may be mounted on the second device stand 44.

In at least one implementation, a mounting bracket 47 may be mounted on a second plane 402. In at least one implementation, a user may mount the electronic device 40 on the second plane 402 when the device stands 43-44 are coupled to the device bracket 422 and the mounting interface 46 for assembling the mounting interface 46 with the mounting bracket 47 on the second plane 402. Thus, the electronic device 40 may be mounted on the second plane 402. In at least one implementation, the second plane 402 may be a wall surface of a wall, or a device surface of a mounting device. In at least one implementation, the mounting device may be a rack, a shelf or a cabinet. In at least one implementation, the second plane 402 may be a vertical plane. In addition, referring to FIG. 1B, the first plane 101 may be a horizontal plane different from the second plane 402. In at least one implementation, the first mounting rail 461 and the second mounting rail 462 mounted on the two device stands 43-44 of the electronic device 40 may be disposed on the mounting bracket 47 mounted on the second plane 402, when the electronic device 40 is moved closer to the second plane 402 for mounting the electronic device 40 on the second plane 402. Then, there may be a plurality of rail connection pin (not shown) for mounting the first mounting rail 461 and the second mounting rail 462 on the mounting bracket 47.

In at least one implementation, a combination of the mounting interface 46 and the mounting bracket 47 may be a flat display mounting interface. In at least one implementation, the combination may be a video electronics standards association (VESA) mount.

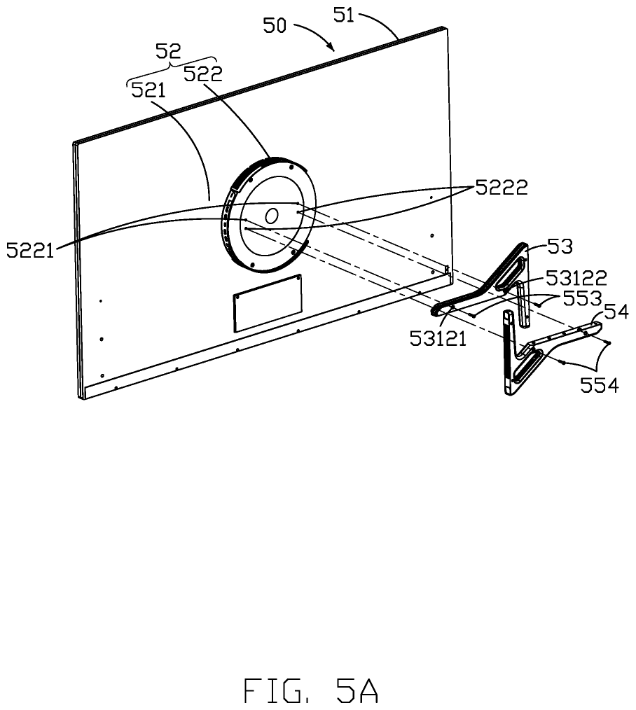

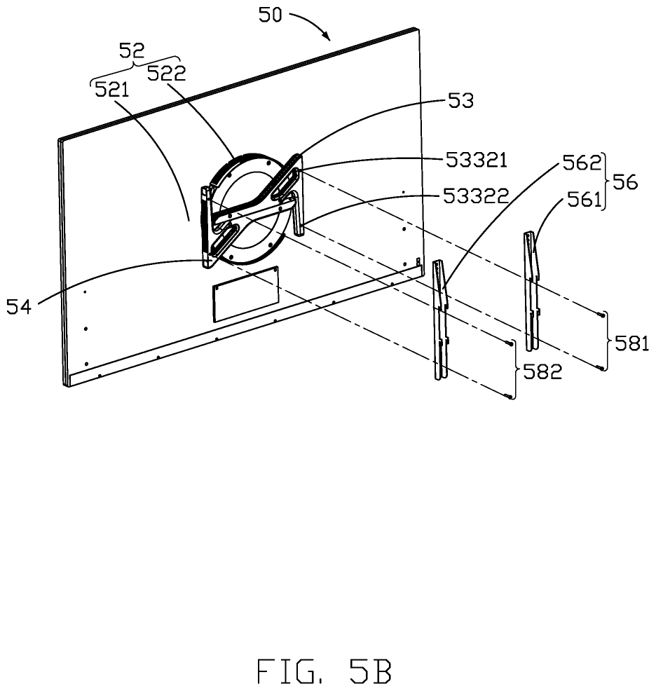

FIG. 5A and FIG. 5B illustrates two exploded views of an electronic device of FIG. 4A in accordance with an embodiment of the present disclosure. In at least one implementation, the electronic device 50 may include an electronic panel 51, a rear cover 521 and a device bracket 522 of a rear panel 52, a first device stand 53, a second device stand 54, a plurality of first bracket connection pins 553 and a second bracket connection pins 554. In at least one implementation, the device bracket 552 may include a plurality of third stand connection holes 5221 and a plurality of fourth stand connection holes 5222. In at least one implementation, the first device stand 53 may include a plurality of second stand holes 53121-53122. In at least one implementation, the electronic device 50 may substantially correspond to the electronic device 40 in FIG. 4A.

In at least one implementation, referring to FIG. 4B, each of the first bracket connection pins 553 may insert into one of the second stand holes 53121-53122 of the first device stand 53 and a corresponding one of the third stand connection holes 5221 for mounting the first device stand 53 on the device bracket 522 of the rear panel 52 when the electronic device 40 is mounted on the second plane 402. In at least one implementation, each of the second bracket connection pins 554 may insert into one of the second stand holes (not shown) of the second device stand 54 and a corresponding one of the fourth stand connection holes 5222 for mounting the second device stand 44 on the device bracket 522 of the rear panel 52.

In at least one implementation, a mounting interface 56 may be mounted on the first device stand 53 and the second device stand 54. In at least one implementation, the mounting interface 56 may include a first mounting rail 561 and a second mounting rail 562. In at least one implementation, the first device stand 53 may include a plurality of third stand holes 53321-53322, and the second device stand 54 may also include a plurality of third stand holes (not shown). In at least one implementation, the first mounting rail 561 may be mounted on the first device stand 53, and the second mounting rail 562 may be mounted on the second device stand 54. In a least one implementation, each of a plurality of first mount connection pins 581 may insert into one of a plurality of fifth stand connection holes (not shown) of the first mounting rail 561 and a corresponding one of the third stand holes 53321-53322 for mounting the first mounting rail 561 on the first device stand 53 which is mounted on the device bracket 522 of the electronic device 50 via the first bracket connection pins 553. In a least one implementation, each of a plurality of second mount connection pins 582 may insert into one of a plurality of sixth stand connection holes (not shown) of the second mounting rail 562 and a corresponding one of the third stand holes (not shown) for mounting the second mounting rail 562 on the second device stand 54 which is mounted on the device bracket 522 of the electronic device 50 via the second bracket connection pins 554. Thus, referring to FIG. 4B, the plurality of mount connection pins 581-582 may insert into the mounting interface 56 and the device stands 53-54 for mounting the electronic device 50 via the mounting interface 56 when the electronic device 50 is mounted on the second plane 402.

From the above disclosure, it may be understood that various techniques may be used for implementing the concepts described in the present disclosure without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

What is claimed is:

1. A device stand for supporting an electronic panel that is covered by a rear panel, the device stand comprising:
a first stand surface having a plurality of first stand holes in a first hole group located thereon; and
a second stand surface intersecting the first stand surface and including a plurality of second stand holes in a second hole group located thereon,
wherein:
the device stand is removably coupled to the rear panel through the plurality of first stand holes when the electronic panel is disposed on a first plane; and
the device stand is removably coupled to the rear panel through the plurality of second stand holes when the electronic panel is mounted on a second plane different from the first plane.

2. The device stand of claim 1, wherein each of a plurality of cover connection pins is inserted into the rear panel and a corresponding one of the plurality of first stand holes when the electronic panel is disposed on the first plane.

3. The device stand of claim 1, wherein each of a plurality of bracket connection pins is inserted into the rear panel and a corresponding one of the plurality of second stand holes when the electronic panel is mounted on the second plane.

4. The device stand of claim 1, wherein:
the second stand surface includes a plurality of third stand holes different form the plurality of the second stand holes; and
the electronic panel is mounted on the second plane by inserting a plurality of mount connection pins into a mounting interface and the plurality of third stand holes.

5. The device stand of claim 1, further comprising:
a stand connection having the plurality of first stand holes and the plurality of second stand holes and removably coupled to the rear panel through one of the first hole group and the second hole group;
a stand arm coupled to the stand connection; and
a stand base coupled to the stand arm,
wherein the stand base is in contact with the first plane when the electronic panel is disposed on the first plane.

6. The device stand of claim 5, wherein:
the stand arm includes two connection arms each intersecting the stand connection; and
a specific one of the plurality of first stand holes is located between the intersections of the two connection arms.

7. The device stand of claim 6, wherein:
one of the two connection arms includes a lock hole aligned with the specific one of the plurality of first stand holes; and
a size of the lock hole is greater than a size of the specific one of the plurality of first stand holes.

8. An electronic device, comprising:
a rear panel having a rear cover and a device bracket and covering on an electronic panel; and
a device stand removably coupled to one of the rear cover and the device bracket,
wherein:
the device stand is coupled to the rear cover when the electronic device is disposed on a first plane; and
the device stand is coupled to the device bracket when the electronic device is mounted on a second plane different from the first plane.

9. The electronic device of claim 8, wherein the device stand comprises:
a stand connection removably coupled to the rear cover when the electronic device is disposed on the first plane and removably coupled to the device bracket when the electronic device is mounted on the second plane;
a stand arm coupled to the stand connection; and
a stand base coupled to the stand arm,
wherein the stand base is in contact with the first plane when the electronic device is disposed on the first plane.

10. The electronic device of claim 9, wherein:
the stand connection includes a first connection surface and a second connection surface different from the first connection surface; and
the rear cover is coupled to the first connection surface when the stand connection is coupled to the rear cover.

11. The electronic device of claim 10, wherein a plurality of cover connection pins is inserted into the rear cover and a plurality of first stand holes on the first connection surface when the stand connection is coupled to the rear cover.

12. The electronic device of claim 11, wherein the stand arm includes two connection arms each intersecting the stand connection; and
a specific one of the plurality of first stand holes is located between the intersections of the two connection arms.

13. The electronic device of claim 12, wherein:
one of the two connection arms includes a lock hole aligned with the specific one of the plurality of first stand holes.

14. The electronic device of claim 13, wherein a size of the lock hole is greater than a size of the specific one of the plurality of first stand holes.

15. The electronic device of claim 10, wherein a plurality of bracket connection pins is inserted into the device bracket and a plurality of second stand holes on the second connection surface when the stand connection is coupled to the device bracket.

16. The electronic device of claim 9, wherein:
the stand base includes a first base surface and a second base surface different from the first base surface; and
the second base surface is on a same plane with the second connection surface.

17. The electronic device of claim 16, wherein the first base surface is in contact with the first plane when the electronic device is disposed on the first plane.

18. The electronic device of claim 16, wherein the electronic device is mounted on the second plane by inserting a plurality of mount connection pins into a mounting interface and a plurality of third stand holes on the second base surface.
